(19) United States
(12) Patent Application Publication
(10) Pub. No.: US 2019/0198804 A1
(43) Pub. Date: Jun. 27, 2019

(54) ORGANIC EL DISPLAY DEVICE

(71) Applicant: Futaba Corporation, Mobara-shi, Chiba (JP)

(72) Inventors: Mitsufumi KODAMA, Mobara-shi, Chiba (JP); Satoshi TANAKA, Mobara-shi, Chiba (JP); Megumi KONNO, Mobara-shi, Chiba (JP)

(21) Appl. No.: 16/329,628

(22) PCT Filed: Jul. 27, 2017
(86) PCT No.: PCT/JP2017/027182

§ 371 Date: Feb. 28, 2019

(30) Foreign Application Priority Data
Sep. 1, 2016 (JP) 2016-170864

(51) Int. Cl. H01L 51/52; H01L 27/32

(52) U.S. Cl. CPC H01L 51/5246; H01L 2251/303; H01L 27/3272; H01L 51/5259

(57) ABSTRACT

An organic EL display device includes a first substrate including a first main surface, a frame-shaped sealing layer in contact with the first main surface, a second substrate in contact with the sealing layer, an organic EL element part disposed in a sealed space S surrounded with the first substrate, the sealing layer and the second substrate, and a filler with which at least an area overlapping the organic EL element part in a layer-stacked direction of the first substrate and the second substrate is filled, in the sealed space. A void is disposed in the sealed space that is positioned between an inner side wall of the sealing layer and a portion which is closest to the inner side wall in the organic EL element part.

### TECHNICAL FIELD

The present invention relates to an organic EL display device.

### BACKGROUND ART

In recent years, as a display device, an organic EL display device which uses an organic electro-luminescence (EL) material as a light-emitting substance is in the spotlight. An organic EL element which is constituted by interposing the organic EL material between a pair of electrodes is likely to be influenced by moisture. For example, deterioration such as oxidation or peeling of the electrode may be generated due to sticking of water. Therefore, a countermeasure against water permeating an area in which the organic EL element is disposed is provided with the organic EL display device.

For example, Patent Literature 1 discloses an organic EL element having a so-called hollow sealing structure. In Patent Literature 1, a water catching agent (drying agent) is disposed in a space (sealed space) which is sealed by an element substrate and a sealing substrate. Patent Literature 2 discloses an organic EL element having a so-called filling and sealing structure. In Patent Literature 2, the sealed space described above is filled with a filler into which a drying agent is dispersed.

### CITATION LIST

### Patent Literature

[Patent Literature 1] Japanese Unexamined Patent Publication No. 2012-038659

[Patent Literature 2] Japanese Unexamined Patent Publication No. 2014-201574

### SUMMARY OF INVENTION

### Technical Problem

In an organic EL display device having a hollow sealing structure as Patent Literature 1 described above, an area in which an inert gas is sealed is disposed, in addition to an area for disposing a water catching agent, in a sealed space. In such an organic EL display device, a difference between a refractive index of the area in which the inert gas is sealed and a refractive index of an element substrate and a sealing substrate is large. Therefore, in a case where light is extracted from the sealing substrate side of the organic EL display device, light-extracting efficiency tends to be low. On the contrary, in an organic EL display device having a filling and sealing structure as Patent Literature 2 described above, a refractive index of a filler is adjusted, thereby, it is possible to improve light-extracting efficiency in comparison with the organic EL display device having the hollow sealing structure.

However, in the organic EL display device having the filling and sealing structure, a deterioration degree of an organic EL element tends to vary in accordance with a position at which the organic EL element is disposed, in comparison with the hollow sealing structure. For example, the closer the organic EL element which is positioned close to an edge of the element substrate or the sealing substrate, the more the organic EL element tends to easily deteriorate. Therefore, in the organic EL display device, both of improvement in light-extracting efficiency and uniformity in deterioration of the organic EL element are desired.

An object of an aspect of the present invention is to provide an organic EL display device that is capable of improving light-extracting efficiency, and is capable of preventing local deterioration.

### Solution to Problem

According to an aspect of the present invention, an organic EL display device includes: a first substrate that has a first main surface; frame-shaped sealing layer that is in contact with the first main surface, and is disposed along an edge of the first substrate; a second substrate that is in contact with the sealing layer, and has a second main surface facing the first main surface; an organic EL element part on the second main surface wherein the organic EL element part is disposed in a sealed space which is sealed by being surrounded with the first substrate, the sealing layer, and the second substrate; and a filler with which at least an area overlapping the organic EL element part in a layer-stacked direction of the first substrate and the second substrate is filled, in the sealed space. A void is disposed in the sealed space that is positioned between an inner side wall of the sealing layer and a portion which is closest to the inner side wall in the organic EL element part.

In the organic EL display device, at least the area overlapping the organic EL element part in the layer-stacked direction is filled with the filler in the sealed space. Therefore, a refractive index of the filler is adjusted, and reflection in the sealed space is reduced, thereby, the organic EL display device can improve light-extracting efficiency in comparison with an organic EL display device having a hollow sealing structure. In addition, the void is disposed in the sealed space that is positioned between the inner side wall of the sealing layer and the portion which is closest to the inner side wall in the organic EL element part. Thereby, water permeating toward a portion which is most likely to be influenced by the water in the organic EL element part from the edge of the first substrate and the sealing layer diffuses into the above-described void of the sealed space. Accordingly, since it is possible to prevent the water which permeates the sealed space from directly permeating the above-described portion of the organic EL element part, it is possible to prevent local deterioration of the organic EL element part.

According to another aspect of the present invention, an organic EL display device includes: a first substrate that has a first main surface; a frame-shaped sealing layer that is in contact with the first main surface and is disposed along an edge of the first substrate; a second substrate that is in contact with the sealing layer, and has a second main surface facing the first main surface; an organic EL element part on the second main surface wherein the organic EL element part is disposed in a sealed space which is sealed by being surrounded with the first substrate, the sealing layer, and the second substrate; and a filler with which at least an area overlapping the organic EL element part in a layer-stacked direction of the first substrate and the second substrate is filled, in the sealed space, in which a void is disposed in the sealed space that is positioned between the edge of the first substrate and a portion which is closest to the edge in the organic EL element part.

In the organic EL display device, at least the area overlapping the organic EL element part in the layer-stacked direction is filled with the filler in the sealed space. Therefore, the refractive index of the filler is adjusted, and the reflection in the sealed space is reduced, thereby, the organic EL display device can improve the light-extracting efficiency in comparison with the organic EL display device having the hollow sealing structure. In addition, the void is disposed in the sealed space that is positioned between the edge of the first substrate and the portion which is closest to the edge in the organic EL element part. Thereby, the water permeating toward the portion which is most likely to be influenced by the water in the organic EL element part from the edge of the first substrate and the sealing layer diffuses into the above-described void of the sealed space. Accordingly, since it is possible to prevent the water which permeates the sealed space from directly permeating the above-described portion of the organic EL element part, it is possible to prevent the local deterioration of the organic EL element part.

When viewed in the layer-stacked direction, a corner part may be disposed in the sealing layer, and the void may be disposed between the corner part of the sealing layer and the filler. In this case, since the water tends to permeate the sealed space in the vicinity of the corner part of the sealing layer from a plurality of directions, the organic EL element part which is disposed close to the corner part is likely to be influenced by the water. Therefore, the void is disposed between the corner part and the filler, thereby, it is possible to prevent the local deterioration of the organic EL element part that is positioned close to the corner part.

When viewed in the layer-stacked direction, the void may be disposed so as to surround the organic EL element part in the sealed space. In this case, since the water which permeates the sealed space firstly diffuses into the whole of the void, it is possible to suitably prevent the water from locally permeating the organic EL element part.

On the first main surface, a groove may be disposed on an outside of the organic EL element part and in the sealed space, and the void may be disposed in at least a portion of the sealed space overlapping the groove. In this manner, the groove is disposed, thereby, the filler is prevented from spreading to the sealing layer, and it is possible to easily dispose the void in the sealed space.

The groove may have a frame shape which surrounds the organic EL element part when viewed in the layer-stacked direction. In this case, the filler is prevented from spreading in the sealed space by the groove, thereby, it is possible to easily dispose the void which surrounds the organic EL element part in the sealed space.

The groove may include a first groove having a frame shape which surrounds the organic EL element part when viewed in the layer-stacked direction, and a second groove having a frame shape which surrounds the first groove when viewed in the layer-stacked direction, and the void may be disposed in at least a portion of the sealed space overlapping the second groove. In this case, the filler is prevented from spreading in the sealed space by the first groove, and it is possible to reliably dispose the void overlapping the second groove in the sealed space.

The organic EL display device may further include a drying agent that is disposed in the sealed space, in which the drying agent may be disposed on at least a part of a surface which forms the void, in the filler. In this case, it is possible to suitably prevent the water which diffuses into the void from permeating a place that is likely to deteriorate in the organic EL element part.

The organic EL display device may further include a drying agent that is disposed in the groove, in which each of the first substrate, the second substrate, and the filler may have light-transmitting properties. In this case, it is possible to suitably prevent the water which diffuses into the void from permeating the place that is likely to deteriorate in the organic EL element part. In addition, since it is possible to make the organic EL display device into a see-through type display device, double-sided light emission of the organic EL display device becomes possible.

The drying agent that is disposed in the groove may have light-shielding properties. In this case, it is possible to prevent the local deterioration of the organic EL element part, without shielding the light which is output to the outside from the organic EL display device, due to the drying agent. Furthermore, the drying agent having light-shielding properties may include a calcium oxide.

A drying agent may be included in the filler. In this case, since the water which permeates into the sealed space is caught due to the drying agent, it is possible to suitably prevent the water from permeating the organic EL element part.

### Advantageous Effects of Invention

According to the aspects of the present invention, an organic EL display device that is capable of realizing improvement in light-extracting efficiency, and prevention in local deterioration is provided.

### BRIEF DESCRIPTION OF DRAWINGS

(a) of FIG. 1 is a schematic plan view of an organic EL display device according to the present embodiment, and (b) of FIG. 1 is a schematic sectional view taken along A-A line in (a) of FIG. 1.

(a) of FIG. 2 is a schematic plan view illustrating a first substrate, and (b) of FIG. 2 is a schematic sectional view taken along B-B line in (a) of FIG. 2. (a) to (c) of FIG. 3 are schematic diagrams for describing a filling method of a filler.

(a) of FIG. 4 is a schematic plan view of an organic EL display device according to Modification Example 1, and (b) of FIG. 4 is a schematic sectional view taken along C-C line in (a) of FIG. 4. (a) of FIG. 5 is a schematic plan view of an organic EL display device according to Modification Example 2, and (b) of FIG. 5 is a schematic sectional view taken along D-D line in (a) of FIG. 5.

(a) of FIG. 6 is a schematic plan view of a first substrate according to Modification Example 3, (b) of FIG. 6 is a schematic sectional view taken along E-E line in (a) of FIG. 6, and (c) of FIG. 6 is a schematic sectional view of a state of being filled with a filler in Modification Example 3.

FIG. 7 is a schematic plan view of an organic EL display device according to Modification Example 4.

(a) of FIG. 8 is a schematic plan view illustrating a light-emitting element for a test, and (b) of FIG. 8 is a schematic sectional view taken along F-F line in (a) of FIG. 8.

FIG. 9 is a graph illustrating light-emitting area changes in Examples 1 and 2, and Comparative Example.

### DESCRIPTION OF EMBODIMENTS

Hereinafter, suitable embodiments of the present invention will be described in detail with reference to the accompanying drawings. In the following description, the same signs are used for the same components, or components having the same function, and the repeated description thereof will be omitted.

A configuration of an organic EL display device according to the present embodiment will be described with reference to FIG. 1. (a) of FIG. 1 is a schematic plan view of the organic EL display device according to the present embodiment, and (b) of FIG. 1 is a schematic sectional view taken along A-A line in (a) of FIG. 1.

As illustrated in (a) and (b) of FIG. 1, an organic EL display device 1 according to the present embodiment is a passive matrix type, and is a see-through type display device. Therefore, in the organic EL display device 1, double-sided light emission becomes possible. The organic EL display device 1 includes a first substrate 2 and a second substrate 3 which are stacked on each other, an organic EL element part 4, wiring portions 5a to 5d, a sealing layer 6, a filler 7, an integrated circuit 8, and an FPC 9 (flexible printed circuit board). Hereinafter, a direction in which the first substrate 2 and the second substrate 3 are stacked on each other will be simply described as a “layer-stacked direction.”

(a) of FIG. 2 is a schematic plan view illustrating the first substrate, and (b) of FIG. 2 is a schematic sectional view taken along B-B line in (a) of FIG. 2. As illustrated in (a) and (b) of FIG. 2 in addition to FIG. 1, the first substrate 2 is a substrate which functions as a sealing substrate, and is disposed to face the second substrate 3. For example, the first substrate 2 is a glass substrate, or a substrate (for example, a plastic substrate or the like) having flexibility, and has light-transmitting properties. A main surface 2a (first main surface) facing the second substrate 3 in the first substrate 2 has a substantially rectangular shape. On the main surface 2a, a groove 2b having a quadrangular frame shape is disposed, when viewed in the layer-stacked direction. For example, a width W1 of the groove 2b is 0.2 to 2 mm. For example, a depth of the groove 2b is 50 μm or more, and is a half or less of a thickness of the first substrate 2.

In the main surface 2a, an edge area 2d on an edge 2c side in comparison with the groove 2b is an area on which the sealing layer 6 is disposed. In the same manner as the groove 2b, the edge area 2d has a quadrangular frame shape when viewed in the layer-stacked direction. For example, a width W2 of the edge area 2d is approximately 1 to 2 mm.

The second substrate 3 is an element substrate on which the organic EL element part 4, and the wiring portions 5a to 5d are disposed. In the same manner as the first substrate 2, for example, the second substrate 3 is a glass substrate, or a substrate (for example, a plastic substrate or the like) having flexibility, and has light-transmitting properties. In the same manner as the main surface 2a, a main surface 3a (second main surface) of the second substrate 3 has a substantially rectangular shape. A short side of the main surface 3a is substantially the same as the short side of the main surface 2a, and a long side of the main surface 3a is longer than the long side of the main surface 2a. Therefore, in a case where the short sides of the main surfaces 2a and 3a are combined, a part of the main surface 3a is exposed from the first substrate 2. For example, a distance between the main surfaces 2a and 3a in the layer-stacked direction is 10 to 30 μm. In the present embodiment, “substantially the same” is a concept which does not indicate entirely the same, but includes a few errors (for example, several % at the maximum).

The organic EL element part 4 is a portion in which an electric current is supplied to generate light, and is disposed on the main surface 3a of the second substrate 3. The organic EL element part 4 is disposed to be surrounded with the groove 2b of the first substrate 2 when viewed in the layer-stacked direction, in a sealed space S which is sealed by being surrounded with the first substrate 2, the second substrate 3, and the sealing layer 6. In other words, when viewed in the layer-stacked direction, the groove 2b is disposed on an outside of the organic EL element part 4 in the sealed space S, and the groove 2b has a frame shape which surrounds the organic EL element part 4. In the organic EL element part 4, a plurality of organic EL elements 11 which are arranged in a matrix, and a cathode separation layer (not illustrated) of which a cross section has a reverse tapered shape are disposed.

For example, each organic EL element 11 is a light-emitting element that has an anode, a cathode, and an organic light-emitting layer which is interposed between the anode and the cathode. For example, an anode is formed on the main surface 3a of the second substrate 3, and an organic light-emitting layer and a cathode are formed in sequence on the anode. For example, as a material which forms the anode, a material such as ITO (indium tin oxide) or IZO (indium zinc oxide) having light-transmitting properties is used. The organic light-emitting layer may have an electron injection layer, an electron transport layer, a hole transport layer, a hole injection layer, and the like, in addition to a light-emitting layer including a light-emitting material. The light-emitting material may be a low molecular organic compound, or may be a high molecular organic compound. As a light-emitting material, a fluorescent material may be used, or a phosphorescent material may be used. For example, as a material (conductive material) of a conductive layer which forms the cathode, aluminum, silver, alkaline earth metal (such as magnesium or calcium), or a material such as IZO (indium zinc oxide) or ITO (indium tin oxide) having light-transmitting properties is used. In a case where the light is output to the first substrate 2 side, the cathode is set to be formed in thickness having light-transmitting properties.

The wiring portions 5a to 5d are portions in which a plurality of lead wires are disposed. Each of the wiring portions 5a, 5b, and 5c is wires that connect the organic EL element part 4 and the integrated circuit 8. The wiring portion 5d is wires that connect the integrated circuit 8 and the FPC 9. At least one of the wiring portions 5a to 5d may be formed at the same time as the anode or the cathode of the organic EL element 11. The lead wires which are included in the wiring portions 5a to 5d is formed of single metal layer, or a stacked metal layer. On a surface of the lead wire, for example, a barrier film such as a silicon oxide film or a silicon nitride film may be disposed.

The sealing layer 6 functions as a bonding agent for bonding the first substrate 2 and the second substrate 3, and functions as a side wall for forming the sealed space S. The sealing layer 6 is disposed along the edge area 2d on the main surface 2a of the first substrate 2, and is in contact with the edge area 2d and the main surface 3a of the second substrate 3. Therefore, the width of the sealing layer 6 is stably formed in accordance with the edge area 2d. The sealing layer 6 is in contact with a part of the lead wires which form the wiring portions 5a to 5c. The sealing layer 6 has a quadrangular frame shape along the shape of the edge area 2d when viewed in the layer-stacked direction. Therefore, the sealing layer 6 is provided with four corner parts 6a to 6d when viewed in the layer-stacked direction. Each of the corner parts 6a to 6d of the sealing layer 6 includes a portion which forms a corresponding internal corner in the sealing layer 6 when viewed in the layer-stacked direction, and a vicinity of the portion. For example, the sealing layer 6 includes an ultraviolet ray curable resin having adhesive properties. The sealing layer 6 may include a spacer such as a silica particle.

The filler 7 is accommodated in the sealed space S, and buries a space in the sealed space S. All of the sealed space S is not filled with the filler 7, and is disposed to bury, for example, approximately 10 to 90% (or approximately 70 to 90%) of the sealed space S. At least an area overlapping the organic EL element part 4 in the layer-stacked direction is filled with the filler 7, in the sealed space S. In addition, the filler 7 is disposed in an area not overlapping the organic EL element part 4 in the sealed space S, and buries a part of the groove 2b. In the present embodiment, the filler 7 is disposed to bury most (approximately 90%) of the sealed space S.

As a filler 7, for example, a liquid-shaped material or a gel-shaped material having light-transmitting properties is used. Visible ray light transmittance of the filler 7 may be 80% or more. As a base material of the filler 7, for example, various curable resins may be used, from the viewpoint of easiness of viscosity adjustment. The filler 7 may include a drying agent having light-transmitting properties. In this case, the visible ray light transmittance of the filler 7 may be 80% or more. Thereby, it is possible to prevent the light which is output to the first substrate 2 side from being shielded while favorably preventing water from permeating the organic EL element part 4 by the drying agent. From the viewpoints of water catching performance, visible light light-transmitting properties, and easiness of viscosity adjustment, a liquid-shaped drying agent which includes a metal alkoxide as a water catching component may be used. The filler 7 may be in a state in which the materials described above are cured.

A void V is disposed in an area which is not filled with the filler 7 in the sealed space S. The void V is provided by separating the sealing layer 6 and the filler 7 from each other, and is formed from, for example, the main surface 2a of the first substrate 2, the main surface 3a of the second substrate 3, an inner side wall 6e of the sealing layer 6, and the surface of the filler 7.

In the present embodiment, the void V is disposed at least in the sealed space S that is positioned between the inner side wall 6e of the sealing layer 6 and a portion which is closest to the inner side wall 6e in the organic EL element part 4. The portion which is closest to the inner side wall 6e in the organic EL element part 4 includes an end side 4a of the organic EL element part 4, the end side 4a being located on a side that is opposite to a side on which the integrated circuit 8 is mounted. More specifically, the portion which is closest to the inner side wall 6e in the organic EL element part 4 is each end side which forms the organic EL element part 4. In a case where a plurality of portions which are closest to the inner side wall 6e are present in the organic EL element part 4, and are separated from each other, the void V may be disposed by corresponding to at least one of the above-described portions, and may be disposed by corresponding to all of the above-described portions. In other words, one void V may be disposed in the sealed space S, or a plurality of voids V may be disposed in the sealed space S. The void V is disposed in a part of the groove 2b, and a portion of the sealed space S overlapping the groove 2b. The void V may be disposed between at least one of the corner parts 6a to 6d of the sealing layer 6 and the filler 7.

In the present embodiment, the void V is disposed to surround the organic EL element part 4 in the sealed space S when viewed in the layer-stacked direction. Therefore, in the present embodiment, the void V is disposed in both of the sealed space S that is positioned between the inner side wall 6e of the sealing layer 6 and the portion which is closest to the inner side wall 6e in the organic EL element part 4, and the sealed space S between the corner parts 6a to 6d of the sealing layer 6 and the filler 7.

The integrated circuit 8 is a driver circuit that controls light emission and non-light emission of each organic EL element 11. The integrated circuit 8 is mounted in the area which is exposed from the first substrate 2 on the main surface 3a of the second substrate 3, and is connected to the wiring portions 5a to 5d. For example, the integrated circuit 8 is an IC chip or the like. The number of the integrated circuits 8 which are mounted on the main surface 3a may be one, or may be plural.

The FPC 9 is connected to the wiring portion 5d, and is wires which connect the organic EL display device 1 and an external device. For example, the FPC 9 is formed using a plastic substrate having flexibility. For example, the external device which is connected to the FPC 9 is a power source, an electric current control circuit, and the like.

Next, an example of a filling method of the filler 7 using ODF (One Drop Filling) method will be described with reference to (a) to (c) of FIG. 3. (a) to (c) of FIG. 3 are schematic diagrams for describing the filling method of the filler. In the description of the filling method, the organic EL element part 4 and the wiring portions 5a to 5d are omitted.

First, as illustrated in (a) of FIG. 3, the first substrate 2 with an adhesive 12 is prepared, the adhesive 12 becoming the sealing layer 6 and being disposed on the edge area 2d. Next, the filler 7 is dropped onto the main surface 2a of the first substrate 2. A dropping amount of the filler 7 is adjusted such that the void V is made in the sealed space S later. A place at which the filler 7 is dropped on the main surface 2a may be one place, or may be a plurality of places.

Next, as illustrated in (b) of FIG. 3, in a low pressure state or a vacuum state, the first substrate 2 is sealed by being overlapped with the second substrate 3. At this time, a pressure is applied to each of the first substrate 2 and the second substrate 3, and an interval between the first substrate 2 and the second substrate 3 in the layer-stacked direction is narrowed. At this time, the filler 7 in the sealed space S spreads to the adhesive 12 side, while burying the void between the second substrate 3 and the filler 7. Therefore, as illustrated in (c) of FIG. 3, a part of the filler 7 intrudes the groove 2b, thereby, spreading of the filler 7 is stopped. Thereby, the void V is formed. After the second substrate 3 is stuck to the first substrate 2, the adhesive 12 is irradiated with an ultraviolet ray in a normal pressure state, and heating is performed onto the adhesive 12, thereby, the sealing layer 6 is formed.

In such an organic EL display device 1 according to the embodiment, the void V is disposed in the sealed space S by separating the sealing layer 6 and the filler 7 from each other. The void V is disposed at least in the sealed space S that is positioned between the inner side wall 6e of the sealing layer 6 and the portion which is closest to the inner side wall 6e in the organic EL element part 4. Thereby, the water permeating toward the above-described portion which is most likely to be influenced by the water in the organic EL element part 4, from the inner side wall 6e of the sealing layer 6, diffuses into the void V in the sealed space S. Accordingly, since it is possible to prevent the water which permeates the sealed space S from directly permeating the above-described portion of the organic EL element part 4, and it is possible to prevent a dark spot or shrinkage from being generated in the portion, it is possible to prevent local deterioration of the organic EL element part 4.

In addition, in the organic EL display device 1, at least the area overlapping the organic EL element part 4 in the layer-stacked direction is filled with the filler 7 in the sealed space S. Therefore, a refractive index of the filler 7 is adjusted, and for example, the refractive index thereof is made substantially the same as the refractive index with the first substrate 2. Thereby, the light is less likely to be reflected at an interface between the filler 7 and the first substrate 2. In other words, it is possible to reduce the number of reflection interfaces in the organic EL display device 1. Thereby, according to the organic EL display device 1, it is possible to improve light-extracting efficiency in comparison with an organic EL display device having a hollow sealing structure.

When viewed in the layer-stacked direction, the corner parts 6a to 6d are disposed in the sealing layer 6, and the voids V are disposed between the corner parts 6a to 6d of the sealing layer 6 and the filler 7. Since the water tends to permeate the sealed spaces S in the vicinity of the corner parts 6a to 6d of the sealing layer 6 from a plurality of directions, portions which are close to the corner parts 6a to 6d in the organic EL element part 4 are likely to be influenced by the water. Therefore, the voids V are respectively disposed between the corner parts 6a to 6d and the filler 7, thereby, it is possible to cause the water permeating the sealed space S through the corner parts 6a to 6d to diffuse into the void V. Thereby, it is possible to prevent the local deterioration of the organic EL element part 4 which is positioned close to the corner parts 6a to 6d.

When viewed in the layer-stacked direction, the void V is disposed to surround the organic EL element part 4 in the sealed space S. Therefore, the water permeating the sealed space S diffuses into the whole of the void V. Thereby, since an amount of the water permeating into the organic EL element part 4 becomes difficult to be biased toward a specific area, it is possible to suitably prevent the water from locally permeating into the organic EL element part 4.

On the main surface 2a, the groove 2b is disposed on the outside of the organic EL element part 4 in the sealed space S, and the void V is disposed in at least a portion of the sealed space S overlapping the groove 2b. In this manner, the groove 2b is disposed, thereby, the filler 7 is prevented from spreading to the sealing layer 6, and it is possible to easily dispose the void V in the sealed space S.

The groove 2b has a frame shape which surrounds the organic EL element part 4 when viewed in the layer-stacked direction. In this case, the filler 7 is prevented from spreading in the sealed space S by the groove 2b, thereby, it is possible to easily dispose the void V which surrounds the organic EL element part 4, in the sealed space S.

The drying agent may be included in the filler 7. In this case, it is possible to suitably prevent the water which permeates the sealed space S from reaching the organic EL element part 4. In a case where the drying agent has light-transmitting properties, it is possible to prevent the light which is output to the first substrate 2 side from being shielded.

Hereinafter, Modification Examples of the embodiment described above will be described with reference to the drawings. In the following description of Modification Examples, the description of a portion which is repeated with the embodiment described above will be omitted.

(a) of FIG. 4 is a schematic plan view of an organic EL display device according to Modification Example 1, and (b) of FIG. 4 is a schematic sectional view taken along C-C line in (a) of FIG. 4. As illustrated in (a) and (b) of FIG. 4, in an organic EL display device 1A according to Modification Example 1, the groove 2b is not disposed in a first substrate 2A. Even in this case, the dropping amount and conditions on the filling method of the filler 7 are adjusted, thereby, it is possible to dispose the void V in the sealed space S. Even in such Modification Example 1, effects which are the same as those of the embodiment described above are accomplished.

(a) of FIG. 5 is a schematic plan view of an organic EL display device according to Modification Example 2, and (b) of FIG. 5 is a schematic sectional view taken along D-D line in (a) of FIG. 5. As illustrated in (a) and (b) of FIG. 5, in Modification Example 2, the groove 2b of a first substrate 2B is filled with a drying agent 21. The first substrate 2B is used, and at least a part of the drying agent 21 is exposed from the filler 7, thereby, at least a part of the surface which forms the void V is formed from the drying agent 21. In such Modification Example 2, since the water which diffuses into the void V is caught by the drying agent 21, it is possible to suitably prevent the water from permeating into the organic EL element part 4.

In Modification Example 2, the drying agent 21 which is disposed in the groove 2b has light-shielding properties. In this case, the drying agent 21 contains oxide particles including an oxide of, for example, an alkaline earth metal. The oxide particles include the oxide of the alkaline earth metal that can have water catching performance. In the oxide particles, the oxide of the alkaline earth metal of 80 mass % or more, or 90 mass % or more is included. As an oxide of the alkaline earth metal, for example, a magnesium oxide (MgO), a calcium oxide (CaO), a strontium oxide (SrO), and a barium oxide (BaO) may be used. The oxide of the alkaline earth metal may be the magnesium oxide and/or the calcium oxide. Such a drying agent 21 is disposed in the groove 2b which surrounds the organic EL element part 4, thereby, it is possible to suitably prevent the water from permeating into the organic EL element part 4, without shielding the light which is output to the outside from the organic EL display device 1A. It is possible to refer to the drying agent having light-shielding properties as a drying agent not having light-transmitting properties.

In Modification Example 2, the drying agent is included in the filler 7, thereby, it is possible to more suitably prevent the deterioration of the organic EL element part 4. The groove 2b is filled with the drying agent 21 to fully bury the groove 2b, but is not limited thereto. For example, the groove 2b may be filled with the drying agent 21 to bury approximately a half of the groove 2b. In this case, a part of the drying agent 21 may be covered with the filler 7.

(a) of FIG. 6 is a schematic plan view of a first substrate according to Modification Example 3, and (b) of FIG. 6 is a schematic sectional view taken along E-E line in (a) of FIG. 6. As illustrated in (a) and (b) of FIG. 6, in Modification Example 3, the groove 2b which is disposed in the main surface 2a of a first substrate 2C has two grooves 31a and 31b. The groove 31a (first groove) has a frame shape which surrounds the organic EL element part 4 when viewed in the layer-stacked direction, and the groove 31b (second groove) has a frame shape which surrounds the groove 31a when viewed in the layer-stacked direction. In other words, the groove 31a which surrounds the organic EL element part 4 is surrounded by the groove 31b. The groove 31b is positioned on an inside of the edge area 2d. A width W3 of the groove 31a is smaller than a width W4 of the groove 31b, but is not limited thereto. That is, the width W3 may be equal to or more than the width W4 or more. The depths of the grooves 31a and 31b are substantially the same, but may be different from each other.

(c) of FIG. 6 is a schematic sectional view illustrating a state of being filled with the filler in Modification Example 3. As illustrated in (c) of FIG. 6, in a case where the sealed space S is filled with the filler 7 using the first substrate 2C, the filler 7 is prevented from spreading to the sealing layer 6 by the groove 31a. Thereby, the filler 7 is less likely to reach up to the groove 31b beyond the groove 31a, and it is possible to reliably dispose the void V overlapping the groove 31b in the sealed space S. Accordingly, in Modification Example 3, it is possible to reliably dispose the void V of the frame shape in the sealed space S, in comparison with the embodiment described above and Modification Examples 1 and 2. In Modification Example 3, the filler 7 may enter the groove 31b.

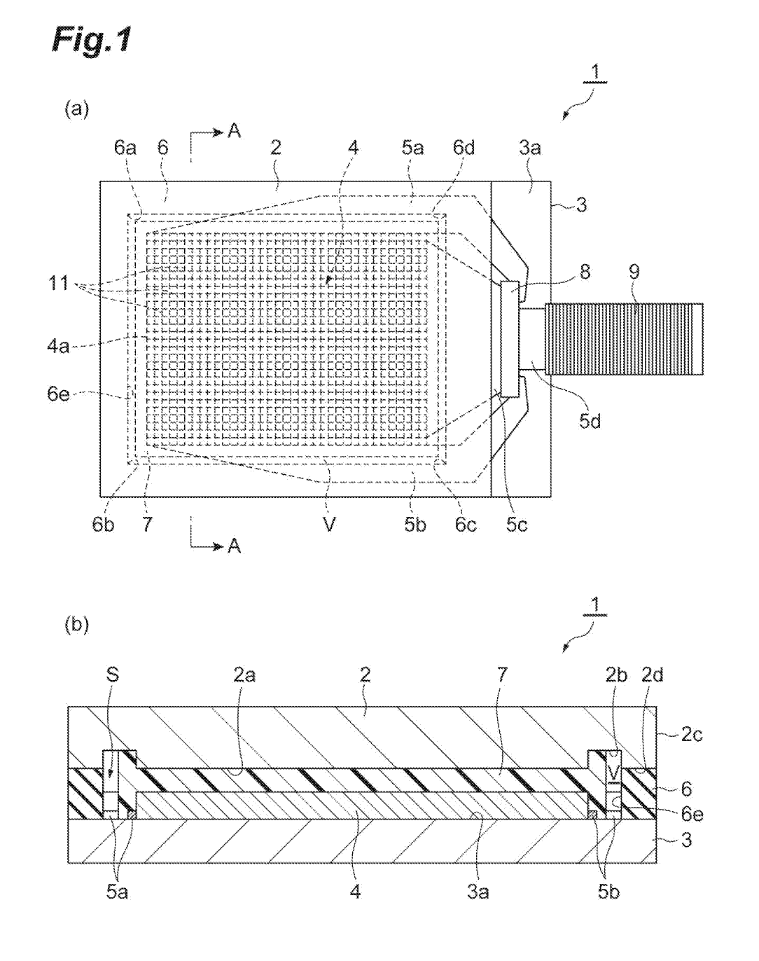

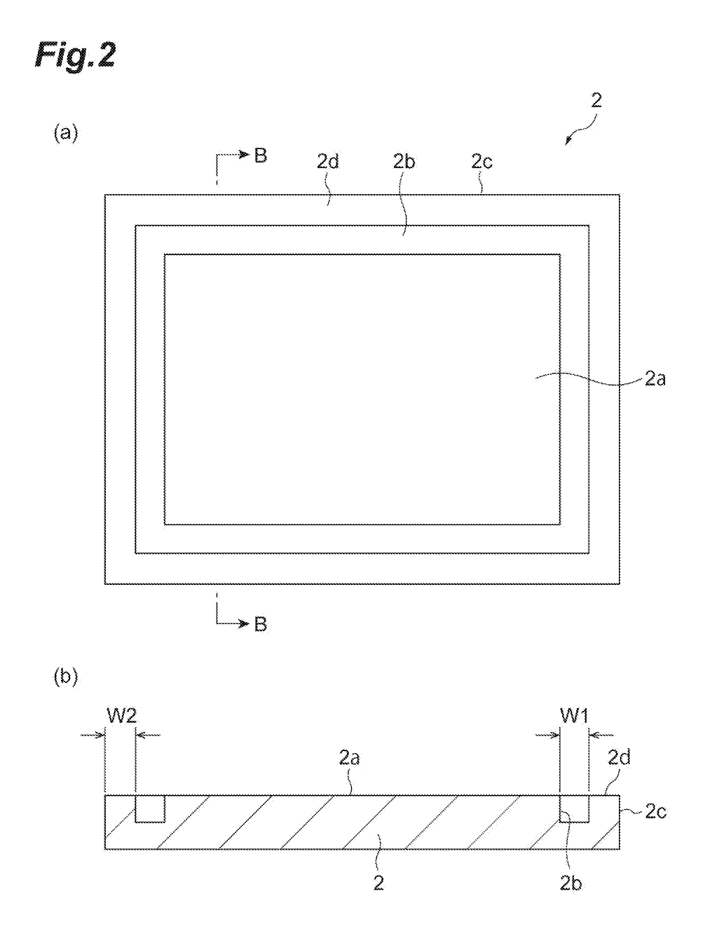

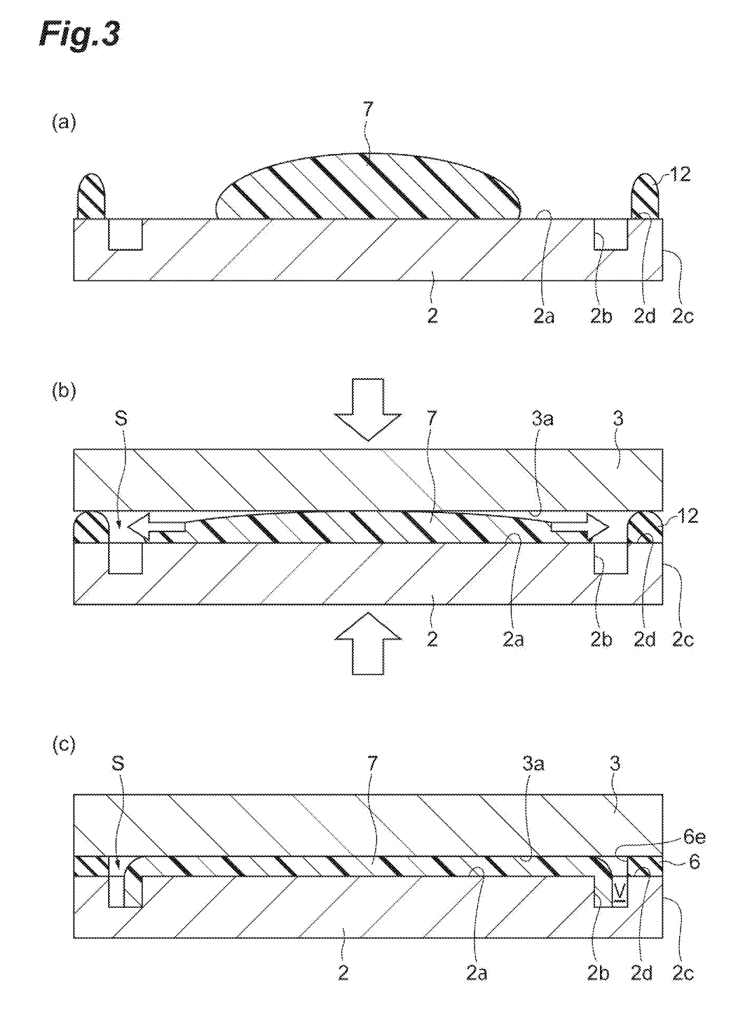

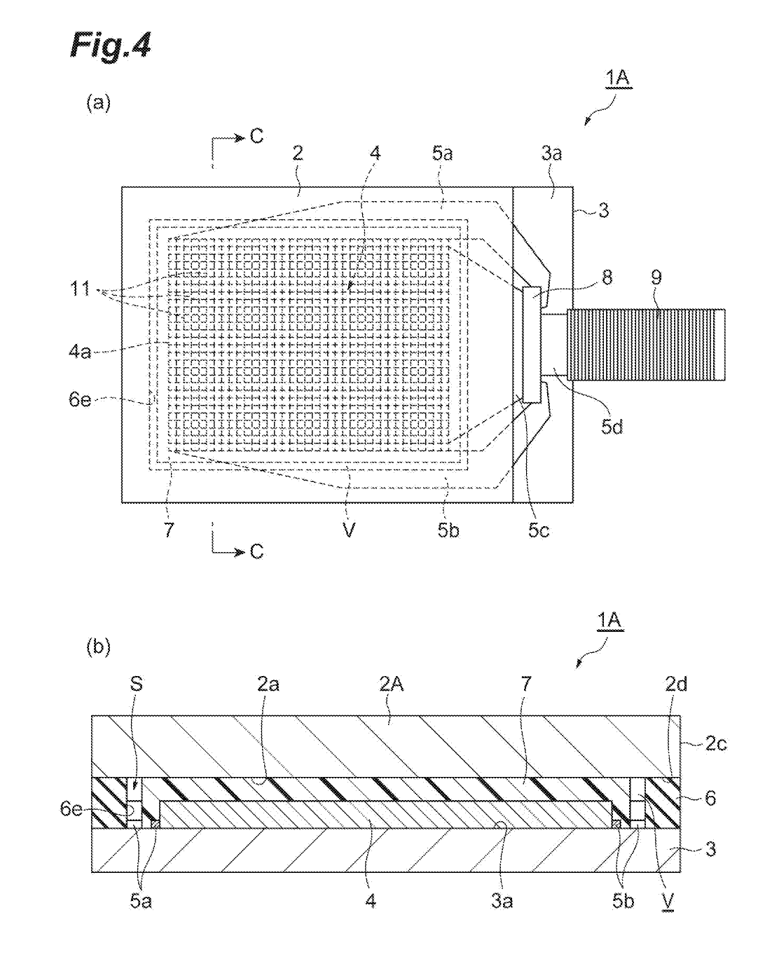

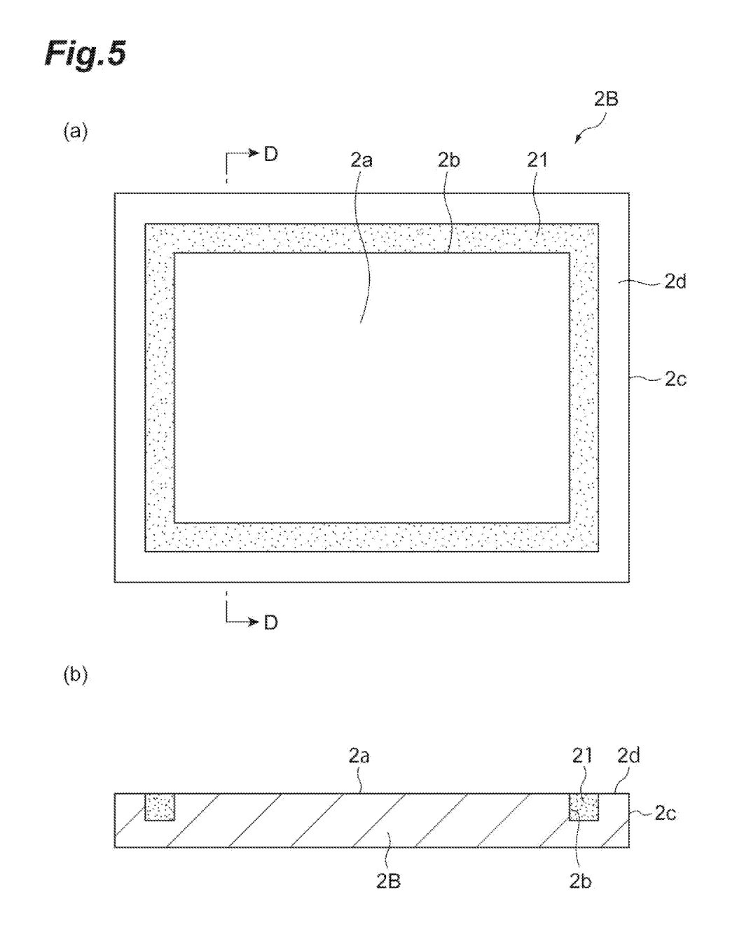

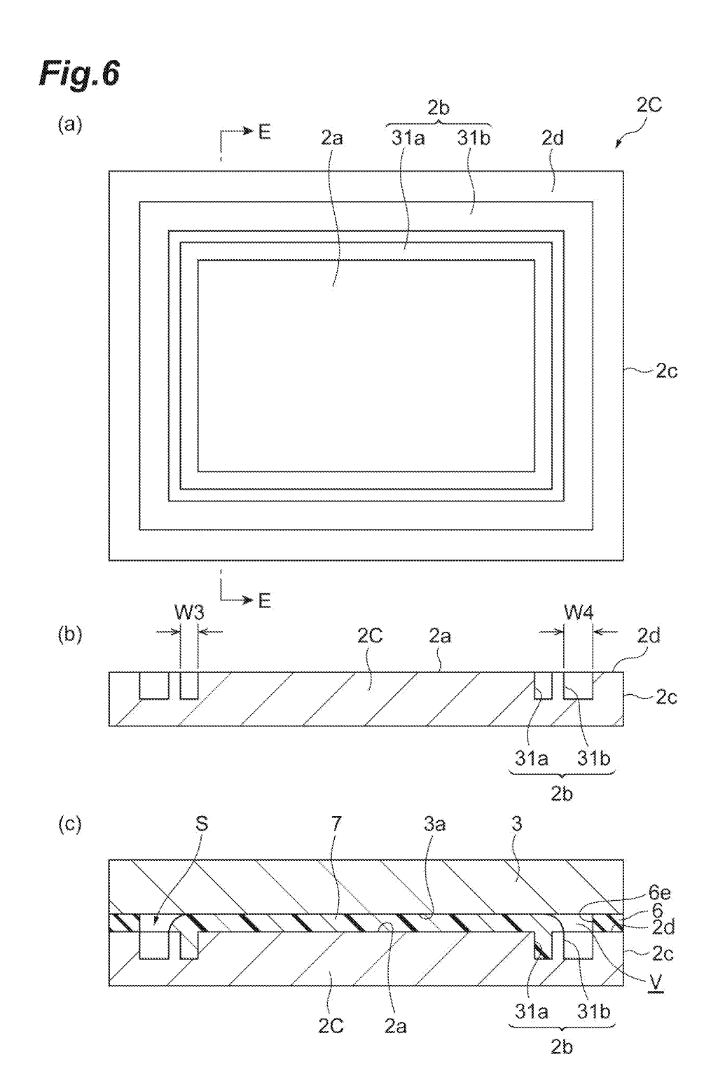

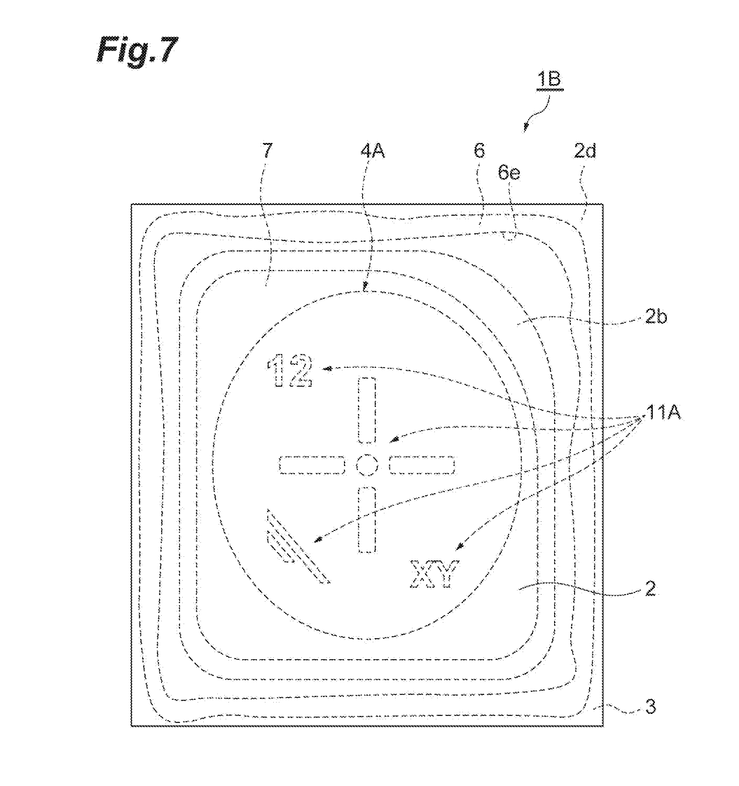

FIG. 7 is a schematic plan view of an organic EL display device according to Modification Example 4. As illustrated in FIG. 7, an organic EL display device 1B in Modification Example 4 is a segment type display device, differently from the embodiment described above. Therefore, it is possible to freely set the shape of an organic EL element 11A when viewed in the layer-stacked direction, in comparison with the embodiment described above. In Modification Example 4, the organic EL elements 11A indicating a numeral, a character, or a figure when viewed in the layer-stacked direction are disposed in an organic EL element part 4A. In such an organic EL display device 1B, in a case where the drying agent is included in the filler 7, a lot of fillers 7 may be disposed close to the organic EL element 11A. In other words, the filler 7 may not spread uniformly in the sealed space. For example, in FIG. 7, most of the grooves 2b which are disposed close to the organic EL element 11A is filled with the filler 7. On the other hand, the groove 2b (groove 2b which is disposed on an upper right side of the organic EL element part 4A on a sheet of FIG. 7) to which the organic EL element 11A is not disposed close is not filled with the filler 7, in contrast to other places. In this manner, a large amount of the filler 7 in which the drying agent is included close to the organic EL element 11A is disposed, thereby, it is possible to suitably catch the water which is to permeate the organic EL element 11A, in addition to the effects which are the same as those of the embodiment described above.

The organic EL display device according to the present invention is not limited to the embodiment and Modification Examples described above, and various modifications are possible, in addition thereto. The embodiment described above and Modification Examples described above may be appropriately combined. For example, Modification Examples 2 and 3 may be combined. In this case, for example, the groove 31b may be filled with the drying agent 21.

In the embodiment described above and Modification Examples 2 to 4, the shape of the groove which is disposed in the first substrate is not particularly limited. For example, the groove may not have the frame shape. The groove may be disposed to overlap the sealed space that is positioned between the edge of the first substrate and a portion which is closest to the edge in the organic EL element part. More specifically, the groove may be disposed to overlap the sealed space that is positioned between the inner side wall of the sealing layer and a portion which is closest to the inner side wall in the organic EL element part.

In the embodiment described above and Modification Examples described above, the void may not be disposed in the sealed space that is positioned between the inner side wall of the sealing layer and the portion which is closest to the inner side wall in the organic EL element part. For example, in a case where a variation in width of the sealing layer is largely generated, the void may be provided in the sealed space that is positioned between the edge of the first substrate and the portion which is closest to the edge in the organic EL element part. In addition, in the embodiment described above and Modification Examples described above, the void may be disposed in at least the sealed space that is positioned between the edge of the first substrate and the portion which is closest to the edge in the organic the EL element part, between the inner side wall of the sealing layer and the portion which is closest to the inner side wall in the organic EL element part.

In the embodiment described above and Modification Examples described above, the sealing layer and a part of the filler are in contact with each other, and other portions are separated from each other, thereby, the void may be disposed. In this case, the void may be defined by the main surface of the first substrate or the main surface of the second substrate, the inner side wall of the sealing layer, and the surface of the filler. In this case, the plurality of voids can be foiled due to a portion with which the sealing layer and the filler are in contact.

In the embodiment described above and Modification Examples 2 to 4, the void may not necessarily be disposed in the groove. If the void is disposed on the groove in the sealed space, all of the grooves may be filled with the filler.

In the embodiment described above and Modification Examples 2 to 4, in a case where the drying agent is at least a part of the surface which forms the void, the drying agent may not be disposed in the groove. For example, the drying agent may be disposed in at least one of the main surface of the first substrate, the main surface of the second substrate, the inner side wall of the sealing layer, and the surface of the filler.

In the embodiment described above and Modification Examples described above, the viscosity of the filler is not particularly limited, but may be a value that is capable of flowing at, for example, room temperature. In this case, the organic EL display device is included, thereby, the filler is capable of flowing in the void. In a case where the drying agent is included in the filler, it is possible to expose the drying agent which does not deteriorate on the surface of the void by the flowing of the filler. Thereby, it is possible to effectively catch the water which permeates the sealed space.

In the embodiment described above and Modification Examples described above, the organic EL display device is not limited to a passive matrix type display device. For example, the organic EL display device may be an active matrix type display device. In this case, a transistor or the like corresponding to each organic EL element is disposed.

In the embodiment described above and Modification Examples described above, the organic EL display device may not be a see-through type display device. For example, at least one of the first substrate and the filler may not have light-transmitting properties.

In the embodiment described above and Modification Examples described above, both of the first substrate and the second substrate are not limited to the substantially rectangular shapes when viewed in the layer-stacked direction. For example, both of the first substrate and the second substrate when viewed in the layer-stacked. direction may have polygonal shapes, or may have substantially circular shapes. In the same manner, the sealing layer which is disposed in the first substrate may have a polygonal frame shape, or may have a substantially annular shape when viewed in the layer-stacked direction. Therefore, the sealing layer may have one corner, or may not have the corner.

### EXAMPLES

The present invention will be described in more detail by Examples hereinafter, but the present invention is not limited to the examples.

(Example 1) (a) of FIG. 8 is a schematic plan view illustrating a light-emitting element for a test, and (b) of FIG. 8 is a schematic sectional view taken along F-F line in (a) of FIG. 8. As illustrated in (a) and (b) of FIG. 8, a first substrate 102 in which a counter boring portion 102b was disposed on a main surface 102a, and a second substrate 103 in which an organic EL element part 104 was disposed were stuck by a frame-shaped sealing layer 106, thereby, a light-emitting element 101 for the test was prepared. In a sealed space S of the light-emitting element 101 for the test, an area which was filled with a filler 107, and an area (void V) which was not filled with the filler 107 were disposed. In the void V on the first substrate 102, a drying agent 121 (manufactured by Futaba Corporation, product name: OleDry P2) was disposed. The counter boring portion 102b is equivalent to the groove 2b in the embodiment described above. Hereinafter, a preparing method of the light-emitting element 101 for the test will be described.

First, the first substrate 102 that was a glass substrate of which the thickness was 0.5 mm was prepared. Next, on the main surface 102a of the first substrate 102, the counter boring portions 102b was formed in a portion not overlapping all of the sealing layer 106 and the organic EL element part 104. Therefore, the drying agent 121 was disposed on counter boring portion 102b.

Separately from the first substrate 102, the second substrate 103 that was a glass substrate was prepared. Next, the organic EL element part 104 was disposed on a main surface 103a of the second substrate 103.

Hereinafter, a forming method of the organic EL light-emitting element in the organic EL element part 104 will be described. First, an ITO film of which the thickness was 135 nm was formed on the main surface 103a. Next, the ITO film was patterned, thereby, an anode was formed. Next, a silicon oxide film of which the thickness was 0.1 μm was formed by a chemical vapor deposition method (CVD method). Next, the silicon oxide film was patterned, thereby, an interlayer insulating film that exposed the anode was formed. Next, the second substrate 103 was cleaned. Next, the dried second substrate 103 was accommodated in a vacuum evaporation device, and an organic light-emitting layer was formed on the anode. Specifically, a hole injection layer of which the thickness was 40 nm, a hole transport layer of which the thickness was 40 nm, a light-emitting layer of which the thickness was 10 nm, an electron transport layer of which the thickness was 65 nm, and an electron injection layer of which the thickness was 2.5 nm were formed in sequence on the anode, thereby, the organic light-emitting layer was formed. Therefore, a cathode was formed on the organic light-emitting layer, thereby, the organic EL element part 104 was formed. Specifically, aluminum of which the thickness was 1 nm, and an IZO film of which the thickness was 100 nm were formed in sequence on the organic light-emitting layer, thereby, the cathode was formed. The IZO film was formed by a sputtering method.

Next, onto an area which was surrounded by the counter boring portion 102b in the main surface 102a of the first substrate 102, the filler 107 was applied using a dispenser. Onto an edge area 102d which surrounded the counter boring portion 102b in the main surface 102a of the first substrate 102, a sealing material of which the thickness was 20 μm was applied using the dispenser. The filler 107 includes a transparent liquid drying agent (manufactured by Futaba Corporation, product name: OleDry F). The sealing material is an ultraviolet ray curable resin (manufactured by ThreeBond Group) into which the spacers are dispersed.

Next, under the reduced pressure, the main surface 102a of the first substrate 102 and the main surface 103a of the second substrate 103 faced each other, and the first substrate 102 and the second substrate 103 were bonded to each other through the sealing material. Next, under the atmospheric pressure, after the sealing material was irradiated with the ultraviolet ray, the first substrate 102 and the second substrate 103 which were bonded to each other were heated under the conditions of 85° C. and 180 minutes. Thereby, the sealing material was cured with the ultraviolet ray, and the sealing layer 106 was formed. At the time of irradiating the sealing material with the ultraviolet ray, the organic EL element part 104 was set to be not irradiated with the ultraviolet ray. Through the processes described above, the light-emitting element 101 for the test in Example 1 was formed.

(Example 2) A light-emitting element for the test was prepared, by a method which was the same as that in Example 1 except that a silicone-based transparent heat-curing type resin (manufactured by Shin-Etsu Chemical Co., Ltd.) was used as a filler 107.

(Comparative Example) A light-emitting element for the test was prepared, by a method which was the same as that in Example 1 except that the counter boring portion 102b was not disposed in the first substrate 102, the drying agent 121 was not disposed on the main surface 102a, and the sealed space S was filled with the filler 107 without the void.

(High Temperature and High Humidity Accelerated Life Test)

A high temperature and high humidity accelerated life test was performed with respect to each of the light-emitting element 101 for the test in Example 1, the light-emitting element for the test in Example 2, and the light-emitting element for the test in Comparative Example, and a change of a light-emitting area of the organic EL element part in each light-emitting element for the test was measured. More specifically, the change of a predetermined organic EL elements (pixel) in each organic EL element part was measured. In the high temperature and high humidity accelerated life test, each light-emitting element for the test was left to stand for approximately 1500 hours under the conditions that the temperature was set to be 60° C., and the humidity was set to be 95%.

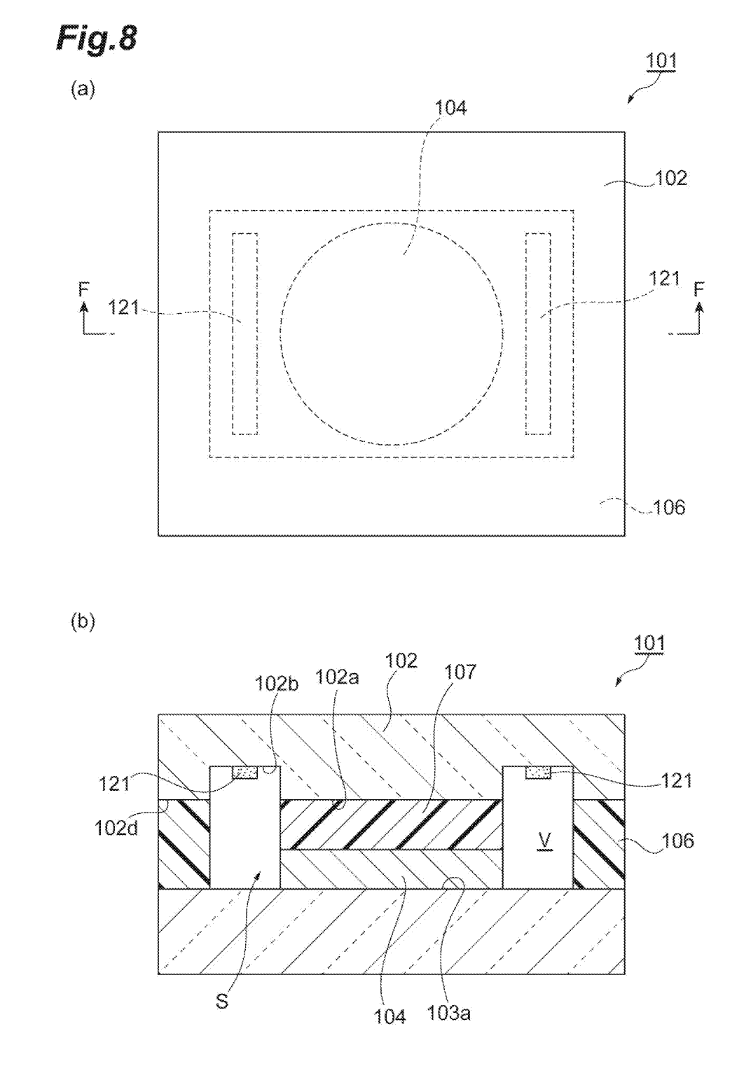

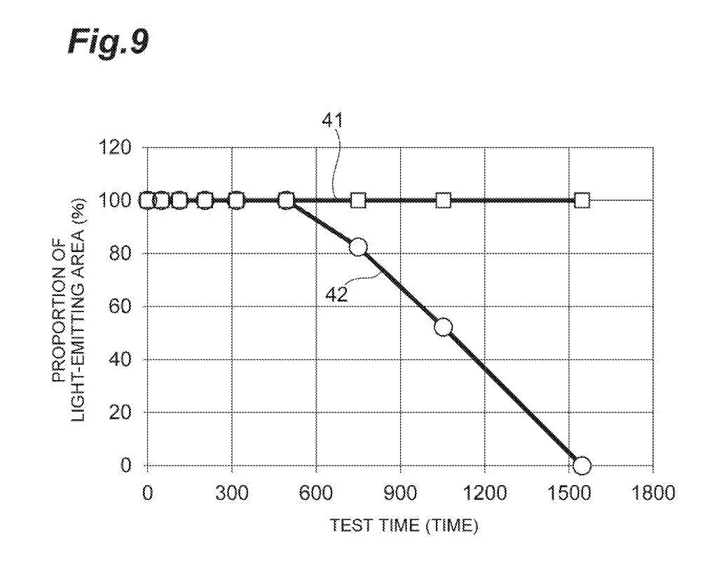

FIG. 9 is a graph illustrating the light-emitting area changes of Examples 1 and 2, and Comparative Example. In FIG. 9, a vertical axis indicates a proportion of an area which emits the light in the organic EL element part, and a horizontal axis indicates test time. A graph 41 illustrates a measurement result of Example 1, and a graph 42 illustrates a measurement result of Comparative Example.

As illustrated in FIG. 9, at the time of a test start, a whole of the organic EL element part in Comparative Example emitted the light. That is, the proportion of the light-emitting area in Comparative Example at the time of the test start was 100%. However, from around the test time exceeding 500 hours, the proportion of the light-emitting area in Comparative Example was lowered. When the test time elapsed approximately 1000 hours, the proportion of the light-emitting area in Comparative Example was approximately 50%. In addition, when the test time exceeded approximately 1500 hours, the proportion of the light-emitting area in Comparative Example was substantially 0.

On the contrary, in Example 1, even in a case where the test time exceeded approximately 1500 hours, the proportion of the light-emitting area was substantially equal to an initial value. In FIG. 9, the change of the light-emitting area in Example 2 was not illustrated, but in Example 2, a result which was substantially equal to that in Example 1 was obtained. That is, in all of Examples 1 and 2, even if the test time exceeded approximately 1500 hours, the proportion of the light-emitting area was substantially equal to the initial value.

From the results, it is found out that durability against the moisture of the light-emitting element for the test is particularly improved, by disposing the void V in at least the sealed space S, and disposing the drying agent 121 in the void V.

### Reference Signs List

1, 1A, 1B: organic EL display device

2, 2A, 2B, 2C: first substrate

2a: main surface (first main surface)

2b: groove

2c: edge

2d: edge area

3: second substrate

3a: main surface (second main surface)

4, 4A: organic EL element part

6: sealing layer

6a to 6d: corner part

6e: inner side wall

7: filler

11, 11A: organic EL element

21: drying agent

31a: groove (first groove)

31b: groove (second groove)

S: sealed space

V: void

W1 to W4: width

1. An organic EL display device comprising:
a first substrate including a first main surface;
a frame-shaped sealing layer in contact with the first main surface, the sealing layer being disposed along an edge of the first substrate;
a second substrate in contact with the sealing layer, the second substrate including a second main surface facing the first main surface;
an organic EL element part on the second main surface, the organic EL element part being disposed in a sealed space surrounded with the first substrate, the sealing layer, and the second substrate; and
a filler with which at least an area overlapping the organic EL element part in a layer-stacked direction of the first substrate and the second substrate is filled, in the sealed space,
wherein a void is disposed in the sealed space that is positioned between an inner side wall of the sealing layer and a portion which is closest to the inner side wall in the organic EL element part.

2. An organic EL display device comprising:
a first substrate including a first main surface;
a frame-shaped sealing layer in contact with the first main surface, the sealing layer being disposed along an edge of the first substrate;
a second substrate in contact with the sealing layer, the second substrate including a second main surface facing the first main surface;
an organic EL element part on the second main surface, the organic EL element part being disposed in a sealed space surrounded with the first substrate, the sealing layer, and the second substrate; and
a filler with which at least an area overlapping the organic EL element part in a layer-stacked direction of the first substrate and the second substrate is filled, in the sealed space,
wherein a void is disposed in the sealed space that is positioned between the edge of the first substrate and a portion which is closest to the edge in the organic EL element part.

3. The organic EL display device according to claim 1,
wherein when viewed in the layer-stacked direction, the sealing layer includes a corner part, and
wherein the void is disposed between the corner part of the sealing layer and the filler.

4. The organic EL display device according to claim 1,
wherein when viewed in the layer-stacked direction, the void is disposed so as to surround the organic EL element part in the sealed space.

5. The organic EL display device according to claim 1,
wherein a groove is disposed on the first main surface, the groove being located on an outside of the organic EL element part and in the sealed space, and
wherein the void is disposed in at least a portion of the sealed space overlapping the groove.

6. The organic EL display device according to claim 5,
wherein the groove has a frame shape which surrounds the organic EL element part when viewed in the layer-stacked direction.

7. The organic EL display device according to claim 5,
wherein the groove comprises a first groove having a frame shape which surrounds the organic EL element part when viewed in the layer-stacked direction, and a second groove having a frame shape which surrounds the first groove when viewed in the layer-stacked direction, and
wherein the void is disposed in at least a portion of the sealed space overlapping the second groove.

8. The organic EL display device according to claim 1, further comprising a drying agent that is disposed in the sealed space,
wherein the drying agent is disposed on at least a part of a surface which forms the void.

9. The organic EL display device according to claim 5, further comprising a drying agent that is disposed in the groove,
wherein each of the first substrate, the second substrate, and the filler has light-transmitting properties.

10. The organic EL display device according to claim 9,
wherein the drying agent has light-shielding properties.

11. The organic EL display device according to claim 10,
wherein the drying agent includes a calcium oxide.

12. The organic EL display device according to claim 1,
wherein a drying agent is included in the filler.

13. The organic EL display device according to claim 2,
wherein when viewed in the layer-stacked direction, the sealing layer includes a corner part, and
wherein the void is disposed between the corner part of the sealing layer and the filler.

14. The organic EL display device according to claim 2,
wherein when viewed in the layer-stacked direction, the void is disposed so as to surround the organic EL element part in the sealed space.

15. The organic EL display device according to claim 2,
wherein a groove is disposed on the first main surface, the groove being located on an outside of the organic EL element part and in the sealed space, and
wherein the void is disposed in at least a portion of the sealed space overlapping the groove.

16. The organic EL display device according to claim 15,
wherein the groove has a frame shape which surrounds the organic EL element part when viewed in the layer-stacked direction.

17. The organic EL display device according to claim 15,
wherein the groove comprises a first groove having a frame shape which surrounds the organic EL element part when viewed in the layer-stacked direction, and a second groove having a frame shape which surrounds the first groove when viewed in the layer-stacked direction, and
wherein the void is disposed in at least a portion of the sealed space overlapping the second groove.

18. The organic EL display device according to claim 2, further comprising a drying agent that is disposed in the sealed space,
wherein the drying agent is disposed on at least a part of a surface which forms the void.

19. The organic EL display device according to claim 15, further comprising a drying agent that is disposed in the groove,
wherein each of the first substrate, the second substrate, and the filler has light-transmitting properties.

20. The organic EL display device according to claim 2,
wherein a drying agent is included in the filler.
